(19) United States
(12) Patent Application Publication
(10) Pub. No.: US 2017/0213908 A1
(43) Pub. Date: Jul. 27, 2017

(54) SELF-ALIGNED SHIELDED-GATE TRENCH MOS-CONTROLLED SILICON CARBIDE SWITCH WITH REDUCED MILLER CAPACITANCE AND METHOD OF MANUFACTURING THE SAME

(71) Applicant: United Silicon Carbide, Inc., Monmouth Junction, NJ (US)

(72) Inventors: Leonid FURSIN, Monmouth Junction, NJ (US); Anup BHALLA, Princeton Junction, NJ (US)

(21) Appl. No.: 15/329,086

(22) PCT Filed: Jul. 1, 2015
(86) PCT No.: PCT/US15/38732

§ 371 Date: Jan. 25, 2017

Related U.S. Application Data
(60) Provisional application No. 62/028,849, filed on Jul. 25, 2014.
(60) Provisional application No. 62/037,969, filed on Aug. 15, 2014.

(51) Int. Cl. H01L 29/78; H01L 29/06; H01L 21/02; H01L 29/40; H01L 29/423; H01L 29/66; H01L 29/739; H01L 29/16

(52) U.S. Cl. CPC H01L 29/7813; H01L 29/7397; H01L 29/0619; H01L 29/0661; H01L 29/1608; H01L 29/407; H01L 29/4238; H01L 29/66068; H01L 29/66325; H01L 29/66734; H01L 21/02271

(57) ABSTRACT

Disclosed herein is a shielded-gate silicon carbide trench MOS-controlled switch, such as a MOSFET or IGBT, with a reduced Miller capacitance. The switch disclosed herein can be used in a variety of applications, including high temperature and/or high voltage power conversion.

### CROSS REFERENCE TO RELATED APPLICATIONS

This application claims the benefit of U.S. Provisional Application No. 62/028,849 filed Jul. 25, 2014 and U.S. Provisional Application No. 62/037,969 filed Aug. 15, 2014, the disclosures of which are hereby incorporated by reference as if set forth in their entirety.

### TECHNICAL FIELD

The disclosed invention is generally in the field of high-current and high-voltage semiconductor devices. More particularly, this invention relates to improved device structures for silicon or silicon carbide trench MOSFET and IGBT switches with shielded gates , and to methods for their manufacture.

### BACKGROUND

High voltage MOS-controlled bipolar semiconductor switches, such as IGBTs and MOSFETs, are of great interest for efficient power management applications in many industries, such as grid-tied renewable energy inverters (such as photovoltaic converters), energy storage, direct current transmission and motor drives (such as for vehicle propulsion), and vehicle traction controls, to name but a few. Of particular interest are trench MOSFETs and IGBTs. They are preferred because they offer more conductive channels per unit area than their planar counterparts. Hence they offer the lower specific on-resistance, and therefore lower device conduction losses. See U.S. Pat. No. 7,633,119 (Bhalla, et al.) titled “Shielded gate trench (SGT) MOSFET devices and manufacturing processes,” granted Dec. 15, 2009, the entirety of which is herein incorporated by reference.

Commonplace devices which attempt to address these needs include normally-off (enhancement-mode) silicon insulated-gate bipolar transistors (IGBTs). With voltage ratings typically in the range of 650 to 6500 V, they may be used for low- and medium-voltage power conversion applications. However, traditional MOS-controlled silicon bipolar switch technology cannot be easily scaled to voltage ratings above 6500 V. To support high voltage in off-state, these devices would require very thick drift layers, and such structures present significant challenges in wafer manufacturing.

Silicon carbide (SiC), arguably the most technologically mature wide-bandgap semiconductor material, is an attractive alternative to silicon for making MOS-controlled switches. Switches made of SiC would theoretically offer higher system efficiency and reduced system weight and size via reduced power losses and higher operating frequencies when compared to similar devices made of silicon.

Despite superior theoretical performance, SiC trench MOSFETs and IGBTs have not yet been commercially available. This is due to significant reliability concerns. When a SiC switch is in an off-state and supporting a high voltage, the gate dielectric may be exposed to electric fields that are much higher than would be seen in an analogous device made of silicon. Gate dielectric rupture, a known concern in for all trench MOS-controlled switches, is therefore of particular concern for SiC devices. Several methods exist for to address this problem. For example, one can provide separate shielding trenches or ion implanted regions, deposit thicker gate dielectric at the bottom of active MOS trenches, and/or implant trench bottoms with dopants that are the opposite of the drift layer in conductivity type.

Another design consideration for these switches is device Miller capacitance. The gate-drain Miller capacitance of a MOSFET (Cgd) or gate-collector Miller capacitance of an IGBT (Cgc) has a significant impact on the device switching capability, especially during turn-on transients. Lowering the Cgd relative to the gate-source capacitance (Cgs) of a MOSFET, or the Cgc relative to the gate-emitter capacitance (Cge) of an IGBT, not only reduces switching losses, but also allows the device to withstand much higher dV/dt transients without re-triggering the gate. The latter is necessary to allow high speed operation. It is very important to minimize the Miller capacitance as much as possible. Lining the bottom of MOS trench with thick dielectric, and introducing a shorted to the MOSFET source (emitter of IGBT) electrode at the bottom of the MOS trench, isolated from the gate, naturally reduces the gate-to-collector capacitance and reduces the gate charge needed to switch the device, as it reduces the part of the MOS gate overlapping the VJFET region. Another intrinsic benefit of such an approach is a reduction of peak electric field in gate-oxide because high field point in center of the JFET region is now covered by a thicker oxide. Introducing an electrode, shorted to the source, within the trench also helps reducing Miller's capacitance and improving device switching performance.

Despite advances in silicon trench MOS-controlled switches, there remains a need for switches with the higher performance of silicon carbide that are more reliable and easier to manufacture.

### SUMMARY

Silicon carbide trench MOSFETs and IGBTs with improved breakdown voltage, reduced conduction and switching losses, and improved robustness under high dv/dt switching conditions are disclosed.

Improvements are achieved by a variety of means, such as: the use of an n-type spreading layer which is doped at least, e.g., 1.5 times higher than the drift layer; orienting trenches close to high-mobility A- or M-crystal planes in silicon carbide, e.g., by deviating no more than 13 degrees of arc; using the same CVD dielectric lining in active MOS trench bottoms and shielding trenches; concurrent oxidation of polysilicon tops and SiC trench sidewalls to form gate oxide and insulation between poly gate and source electrode; using concurrently deposited and doped trench-based source electrodes and polysilicon gate areas; creating shielding trenches that are at least 100 nm deeper than active MOS trenches; and using shielding trenches in less than 50% of the area occupied by active MOS trenches, e.g., by avoiding the need to use of shielding trenches every unit cell.

Also disclosed herein are circuits and larger devices that use the silicon carbide semiconductor MOSFET and IGBT switches described herein.

### BRIEF DESCRIPTION OF THE DRAWINGS

The summary, as well as the following detailed description, is further understood when read in conjunction with the appended drawings. For the purpose of illustrating the inventive concepts, the drawings show exemplary embodiments of the invention. However, the invention is not limited to the specific methods, compositions, and devices disclosed. Please note that the drawings are not necessarily drawn to scale.

FIG. 1 is a cross-sectional view of an embodiment of the present invention comprising a silicon carbide trench shielded-gate MOSFET with reduced Miller capacitance.

FIG. 2 shows another cross-sectional view of the structure depicted in FIG. 1, highlighting an exemplary way to form electrical connections to the gate electrode, and to the MOS trench-based polysilicon source electrode.

FIGS. 3-21 are cross-sectional views illustrating exemplary methods for fabricating a silicon carbide trench shielded-gate MOSFET with reduced Miller capacitance.

FIG. 3 is a cross-sectional view of an exemplary starting wafer structure.

FIG. 4 illustrates formation of an implanted region, and connecting p-base to the surface.

FIG. 5 illustrates deposition of an etching mask to form device trench structure.

FIG. 6 illustrates a trench etching process with reactive -ion etching/inductively coupled plasma (RIE/ICP).

FIG. 7 illustrates a deeper etching process for creating shielding trenches.

FIG. 8 illustrates conformal deposition of a thick CVD dielectric trench liner.

FIG. 9 illustrates filling a trench with CVD polysilicon.

FIG. 10 illustrates etch-back of deposited polysilicon to provide trench fill.

FIG. 11 illustrates selective etching of thick CVD dielectric on device top surface.

FIG. 12 illustrates formation of MOS trench-based polysilicon source electrode with selective etch of poly-silicon.

FIG. 13 illustrates further selective etching of thick CVD dielectric in upper portions of MOS trenches.

FIG. 14 illustrates formation of MOS gate oxide and thick inter-layer dielectric (ILD) oxide over polysilicon trench-based source electrode.

FIG. 15 illustrates CVD deposition of polysilicon gate electrode.

FIG. 16 illustrates etch-back of deposited polysilicon to define MOS gate regions.

FIG. 17 illustrates deposition and planarization of additional inter-layer dielectric (ILD).

FIG. 18 illustrates etch-back of deposited ILD dielectric to expose ohmic contact regions.

FIG. 19 illustrates formation of a topside ohmic contact.

FIG. 20 illustrates formation of a topside metal overlay.

FIG. 21 illustrates formation of a backside ohmic contact and a metal overlay.

FIG. 22 is a cross-sectional view of an embodiment of the present invention comprising a silicon carbide trench shielded-gate IGBT with reduced Miller capacitance.

FIG. 23 illustrates cross-sectional view of an embodiment of the present invention comprising a silicon carbide trench shielded-gate IGBT with reduced Miller capacitance and optimized minority carrier injection into drift layer using discontinuous (patterned) backside p-type ohmic contact regions.

FIG. 24 illustrates a schematic device die layout of another exemplary embodiment of the present invention with parallel orientation of shielding and MOS trenches.

FIG. 25 illustrates a schematic device cell layout of another exemplary embodiment of the present invention, staggered closed cell arrangement of shielding and MOS trenches.

FIG. 26 illustrates a schematic device cell layout of another exemplary embodiment of the present invention, with a hexagonal cell arrangement of shielding and MOS trenches.

FIG. 27 illustrates a schematic device cell layout of another exemplary embodiment of the present invention, with a circular cell arrangement of shielding and MOS trenches.

FIG. 28 illustrates a schematic device cell layout of another exemplary embodiment of the present invention, with a circular or rectangular arrangement of backside implanted p++ regions to provide ohmic contacts to IGBT p-type minority carrier injector.

FIG. 29 illustrates a schematic cross-sectional view of exemplary embodiment of the present invention, an edge termination region comprising etched bevel and junction-termination extension region.

FIG. 30 illustrates a schematic cross-sectional view of exemplary embodiment of the present invention, an edge termination region comprising etched bevel and multiple floating guard rings.

FIG. 31 illustrates a full bridge circuit schematic of an exemplary embodiment of present invention, where a shielded-gate n-channel MOSFET is being used with an antiparallel diode.

FIG. 32 illustrates a full bridge circuit schematic of an exemplary embodiment of present invention, where a shielded-gate n-channel IGBT is being used with an antiparallel diode.

### DETAILED DESCRIPTION OF ILLUSTRATIVE EMBODIMENTS

The present invention may be understood more readily by reference to the following detailed description taken in connection with the accompanying figures and examples. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention.

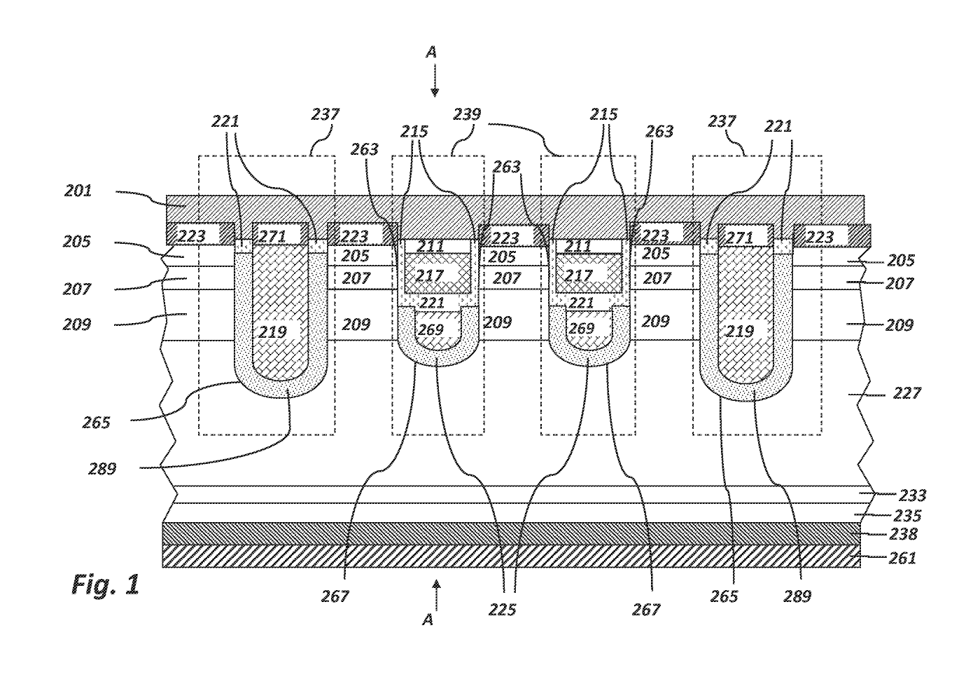

FIG. 1 illustrates an exemplary embodiment of present invention, one of many possible shielded-gate trench MOSFET (or IGBT) configurations with reduced Miller capacitance according to the inventive concepts, comprising active MOS trench regions 239 alternating with shielding trench regions 237. An active MOS trench comprises a topside MOSFET source (or IGBT emitter) ohmic contact 223 and an optional ohmic contact 271 to the shielding trench polysilicon fill with a topside overlay 201 to facilitate wire bonding, a tops ide n-type contact region 205 and a p-base 207. P-base 207 is electrically connected to the topside ohmic contact electrode 223 via high dose p+ implants 205 within each device unit cell. MOS channels 263 are formed the between p-base regions 207, a MOS gate oxide 215 on the MOS trench side-walls, and a degenerately doped polysilicon gate electrode 217. Gate electrode 217 is electrically insulated from the source overlay 201 by interlayer dielectric 211. Gate electrode 217 is connected to an individual gate pad in specific location within device die for wafer-level testing and wire-bonding. Region 209, which is a current-spreading layer (or a carrier storage layer for an IGBT), is n-type doped and facilitates current conduction between a low doped n-type drift layer 227 and the MOS-channel 263. The bottom of active MOS trenches 267 and bottom of shielding trenches 265 are lined up with thick CVD dielectric regions 225 and 289, respectively. The CVD dielectric layers 225 and 289 may optionally include thin silicon dioxide layer that is thermally grown on silicon carbide trench surface. Both the active MOS trenches 267 and the shielding trenches 265 are filled with degenerately doped polysilicon regions 269 and 219, respectively. E.g., polysilicon regions 269 and 219 may be doped with phosphorus at about 10²⁰ cm⁻³ volumetric concentration. Polysilicon regions 269 and 219 are preferably formed concurrently with a single CVD deposition, but are etched differently. The polysilicon region of the shielding trench 219 is connected to the source overlay 201 via ohmic contact 271, which is formed at the same time as source ohmic contact 221. The MOSFET switch further comprises a buffer layer 233, which may be an epitaxial n-type layer, and an n-type doped region 235 to facilitate backside MOSFET drain ohmic contact 238. Region 235 may be formed as an original wafer substrate and possibly include ion implantation. The backside ohmic contact 238 is coated with backside overlay 261 for die-mounting.

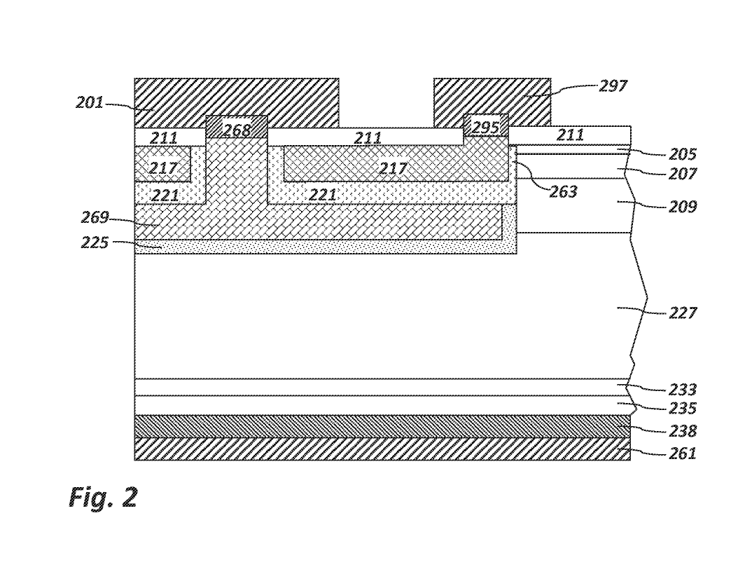

FIG. 2 corresponds to cross-section A-A of FIG. 1. As FIG. 2 shows, the MOS trench-based polysilicon source electrode 269 may be connected to the source overlay 201 via a contact 268 at a certain region or regions within the device cell. Polysilicon region 269, which is shorted to the source, helps to reduce the Miller capacitance of the switch. As also illustrated by FIG. 2, an electrical connection to the MOS gate region 217 may be provided within a certain region at a periphery of a device or cell, via ohmic contact 295 and gate overlay 297. The window for contact 295 may be opened with a separate photolithography and etching step. As FIG. 1 further shows, polysilicon region 269 is electrically isolated from the active MOS-gate electrode 217 by the thick silicon dioxide layer 221, which is formed of oxidized polysilicon concurrently with MOS gate oxide 215. The oxidation rate of polysilicon is higher than that of silicon carbide under same conditions, and hence the thicker dielectric 221 may be formed concurrently with the thinner gate oxide 215.

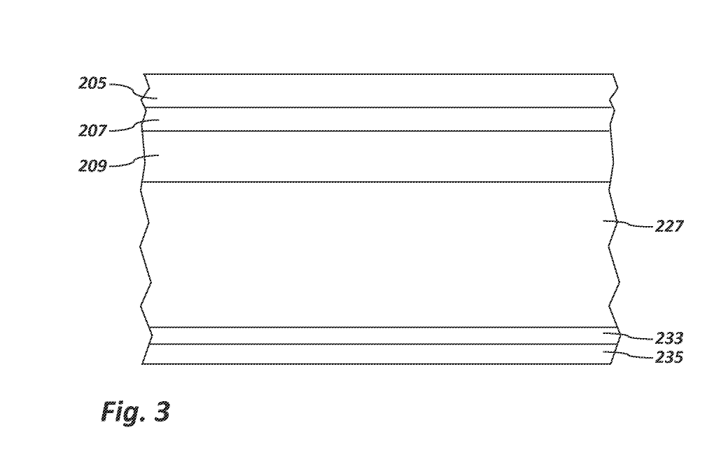

FIGS. 3-21 illustrate an exemplary embodiment of the present invention in a sequence of manufacturing steps for fabricating a trench shielded-gate n-channel MOSFET with a MOS trench-based degenerately doped polysilicon source electrode.

FIG. 3 shows the initial wafer structure with starting a substrate 235, an epitaxial n-type buffer layer 233 between the substrate and a drift layer 227, a current-spreading layer 209, a p-base layer 207 and a source n-type layer 205. The current-spreading layer 209, p-base layer 207 and source layer 207 may be epitaxially grown or ion-implanted.

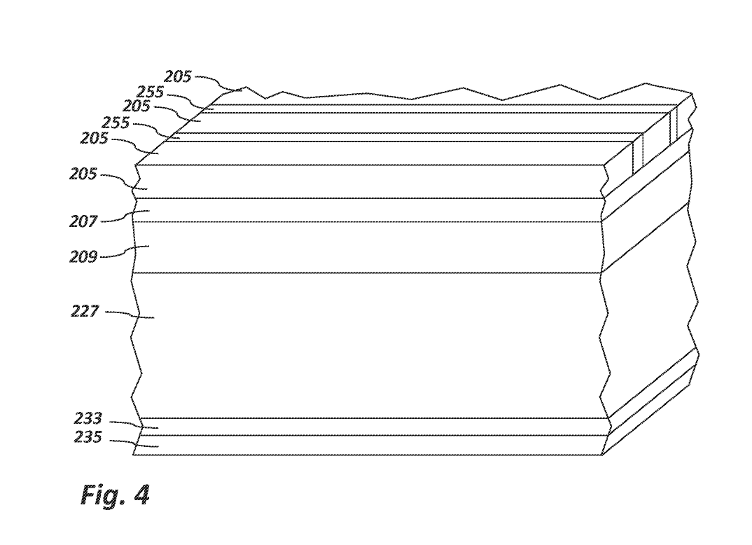

Referring to FIG. 4, ion implantation of source layer 205 is preferred as an easy way to provide heavily doped p+ material to for electrical connection of the p-base 207 to the surface. Here implanted high-dose p+ regions 255 are depicted as alternating with n-type source regions 205. Alternative, instead of ion implantation, these high dose p+ regions may be formed by etching shallow trenches through layer 205 and subsequently using epitaxy to re-fill of the trenches, e.g., through epitaxial re-growth of the p+ layer and etch-back of regrown planar layer with ICP or RIE fluorine plasma, so that only p+ trench fill is left.

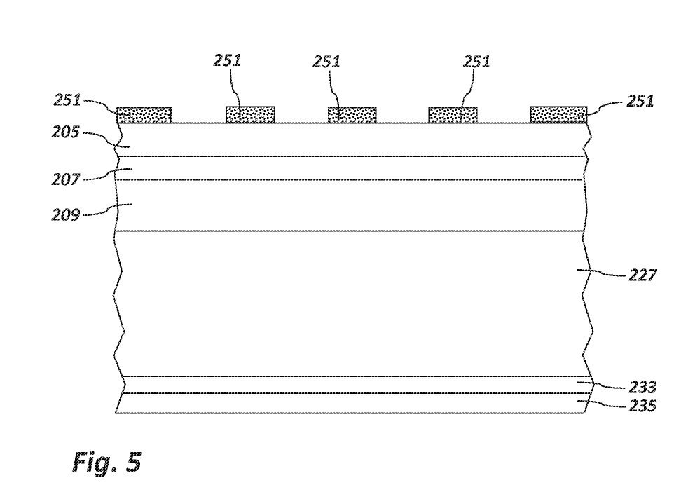

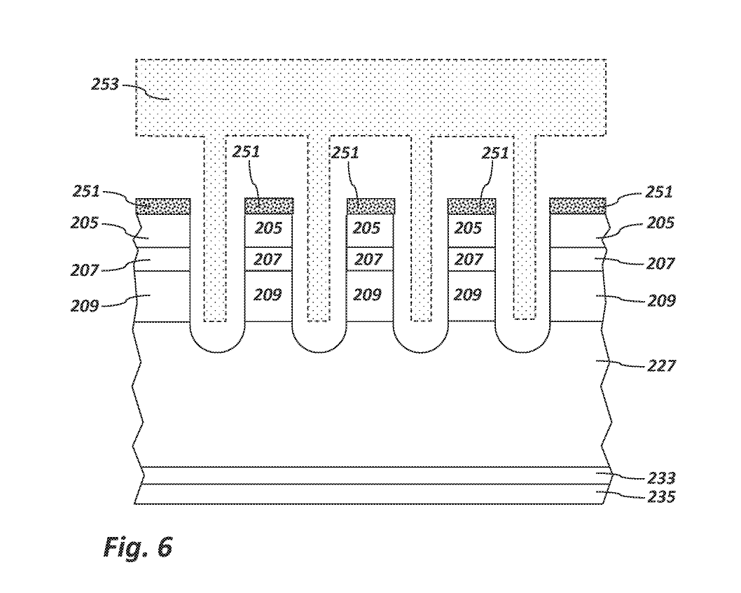

FIG. 5 illustrates deposition of trench etching mask pattern 251. This may be achieved by lift-off, wet etching, combination of these two methods, or equivalent means. Mask layer 251 shields the underlying silicon carbide surface from plasma etching. Mask layer 251 may include a combination of metal layers, such as nickel, aluminum, titanium and others, and CVD dielectrics, such as silicon dioxide. As FIG. 6 illustrates, trenches are etched through the source, p-base and current spreading layers with either RIE or ICP plasma 253, to reach into the drift layer.

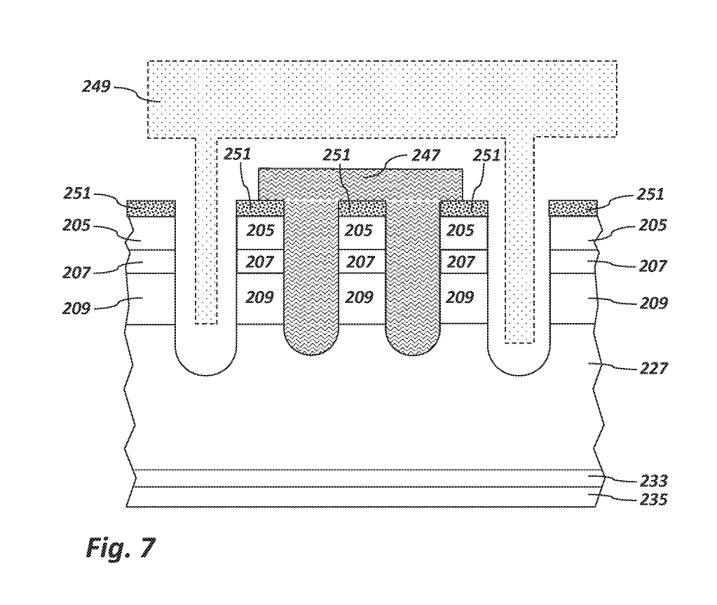

FIG. 7 illustrates further etching of shielding trenches to make them deeper than the adjacent MOS trenches. This is accomplished by depositing an additional etching mask 247, e.g., a photoresist, to cover the MOS trenches. Depositing such an additional masking layer does not require any critical photolithographic alignment. The etching plasma 249 then proceeds to deepen the shielding trenches. Afterward, etching mask 247 material is removed.

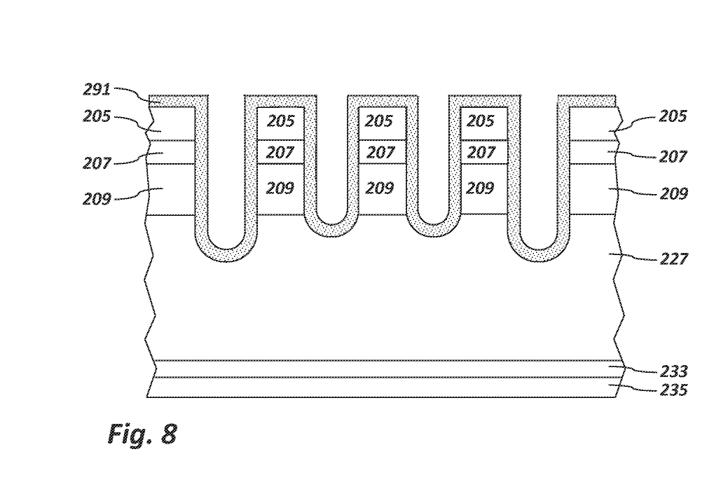

FIG. 8 illustrates deposition of a thick CVD dielectric trench liner with possible preceding growth of a thin thermal oxide 291. CVD deposition provides nearly conformal coating over all wafer surfaces, including the trench walls.

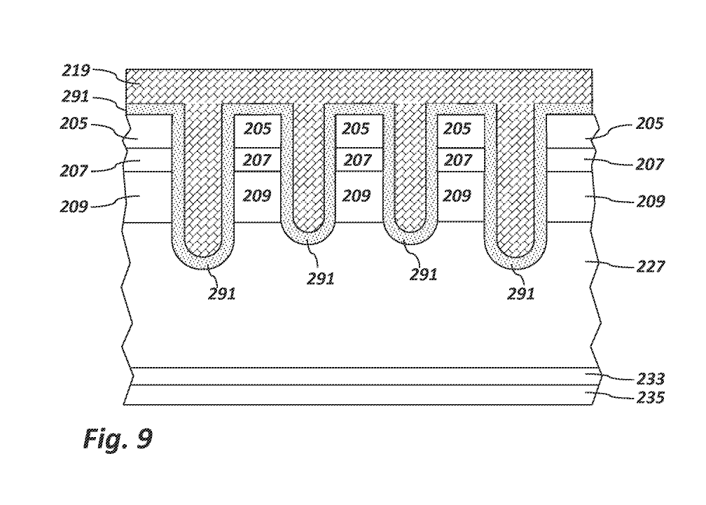

FIG. 9 illustrates CVD deposition of a polysilicon layer 219 to fill both the shielding and MOS trenches. Polysilicon layer 219 may be degenerately doped in-situ during growth. Alternatively, polysilicon layer 219 may be doped from a spin-on diffusion source or via ion implantation, with subsequent diffusion throughout the bulk of polysilicon and activation with drive-in annealing.

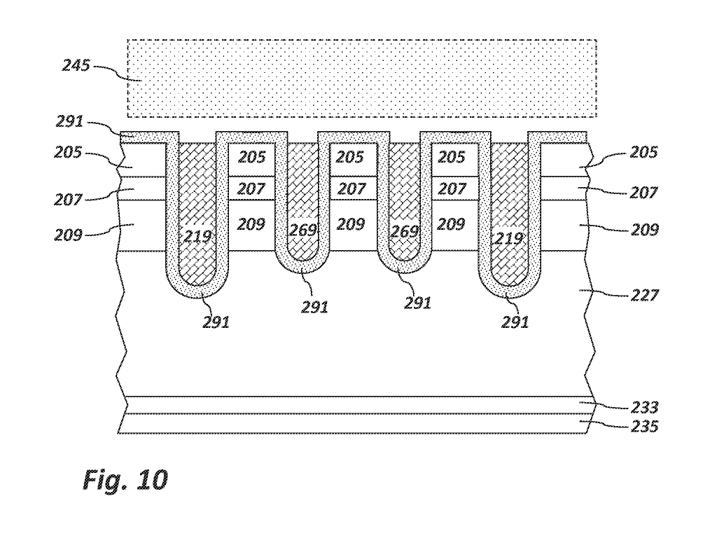

As FIG. 10 illustrates, polysilicon layer 219 may be etched back with blanked RIE or ICP plasma 245, so that the polysilicon filling regions within the shielding trenches 219 are left isolated from the polysilicon filling regions within the MOS trenches 269.

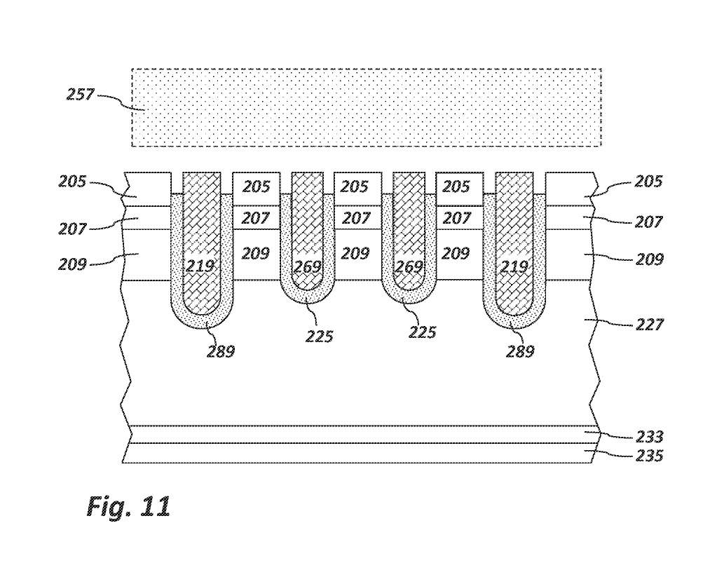

As illustrated by FIG. 11, the CVD and optional layer of thermal oxide 291 may be etched with selective etchant 257, which is either wet etchant containing hydrogen fluoride or an RIE/ICP plasma, resulting in layer 291 being divided into separate MOS trench dielectric liner 225 and shielding trench dielectric liner 289. This etching has to be very selective to polysilicon.

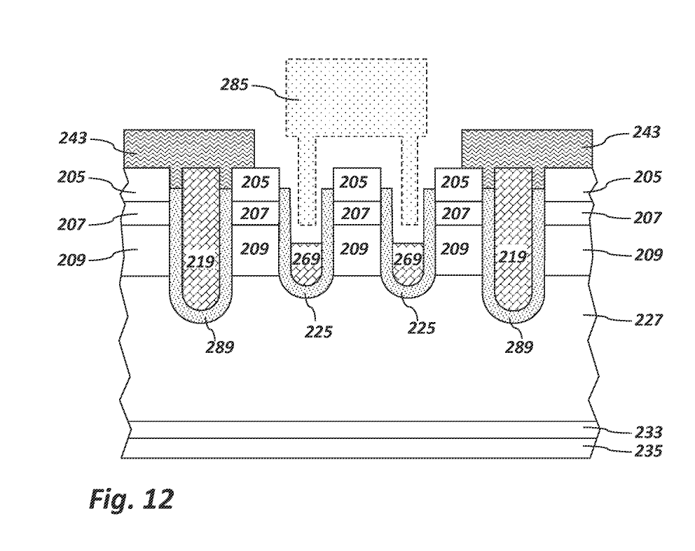

As illustrated by FIG. 12, the polysilicon in the shielding trenches 219 is then covered with a plasma etching mask 243, such as a photoresist. The exposed polysilicon in MOS trenches 269 is then further etched with an RIE/ICP plasma 285. Plasma etching chemistry, such as chlorine-based, has to provide selective etch of polysilicon to both the CVD dielectric in the trenches and silicon carbide. This etching step defines MOS trench-based degenerately doped polysilicon source electrode regions 269.

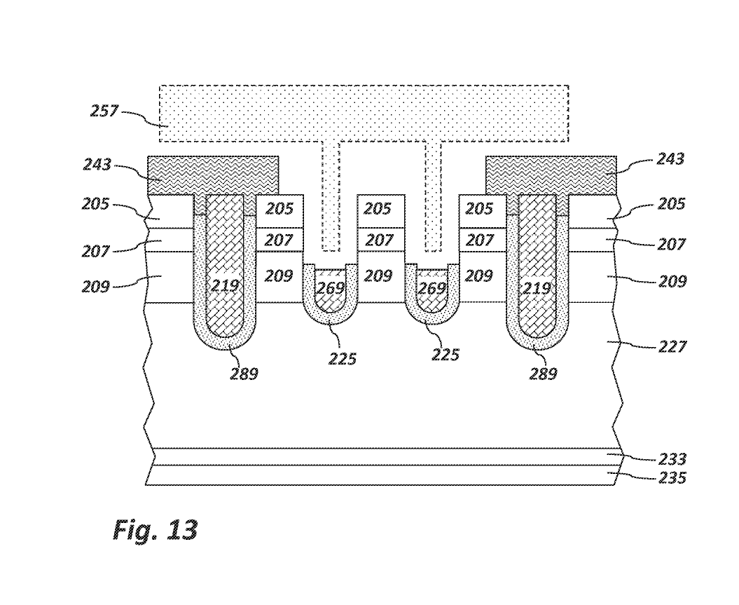

As FIG. 13 shows, the CVD and optional layer of thermal oxide 225 above the MOS trench-based degenerately doped polysilicon source electrode 269 are next further etched with selective etchant 257, which is either wet etchant containing hydrogen fluoride, or a RIE/ICP plasma. Etching mask 243 is subsequently removed with a combination of solvents, photoresist stripper chemical and oxygen plasma.

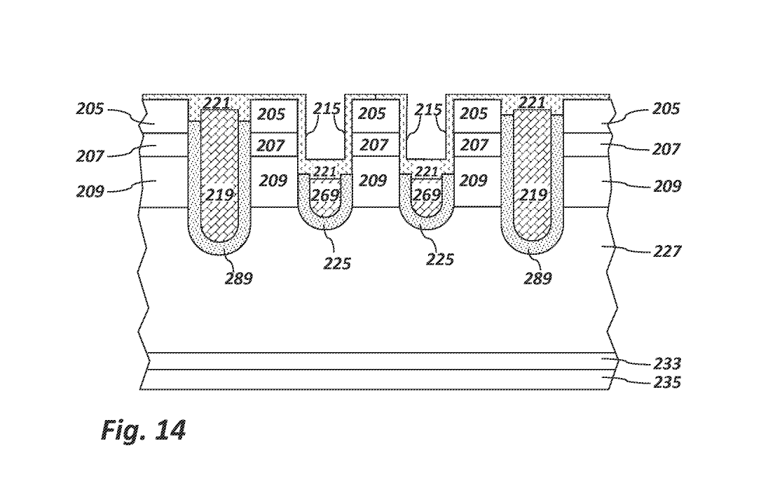

As FIG. 14 illustrates, a MOS gate thermal oxide 215 (30-100 nm thick) is subsequently thermally grown on exposed silicon carbide MOS trench surfaces. This step also oxidizes the exposed top surfaces of polysilicon regions 219 and 269. Again, the oxidation rate of polysilicon is significantly higher than that of silicon carbide under same conditions, such as in dry oxygen at 950-1200 degrees C. Therefore the thermal oxide 221 that grows on top of the polysilicon is thicker than the MOS gate oxide 215.

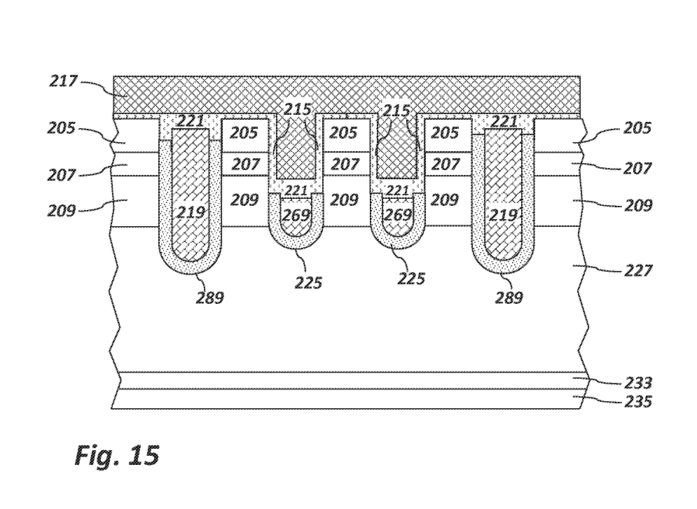

As illustrated in FIG. 15, a layer of polysilicon 217 is subsequently deposited by CVD method to fill the MOS trenches. Polysilicon 217 may be degenerately doped in-situ during growth. Alternatively dopants may be introduced from the spin-on diffusion source or by ion implantation. Drive-in diffusion at 950-1150 degrees C. distributes the dopants throughout the entire polysilicon film thickness, and activates the implants.

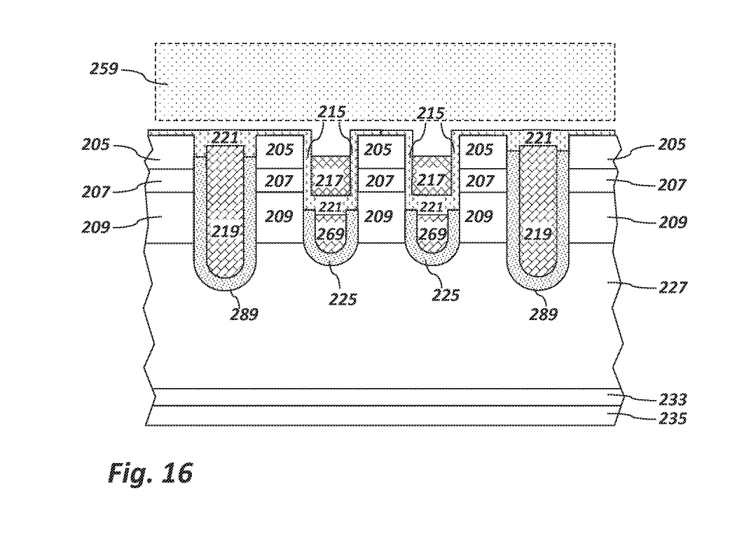

FIG. 16 illustrates the definition of polysilicon MOS gate regions 217 through etching with an RIE/ICP plasma 259. A selective plasma etchant, such as a chlorine-based etchant, is required to selectively etch polysilicon 217 more than thermal oxide 221.

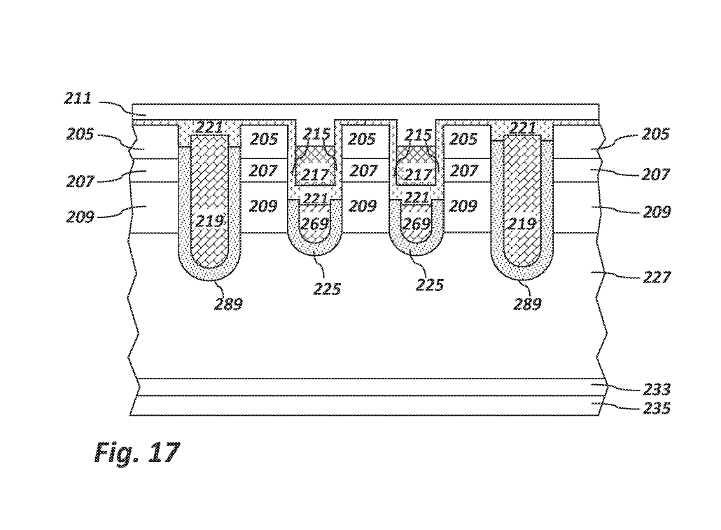

As FIG. 17 shows, an additional planarizing interlayer dielectric 211 is deposited over the entire die. Planarizing interlayer dielectric 211 may be a multi-layer combination of CVD silicon dioxide, spin-on glass, and silicon nitride.

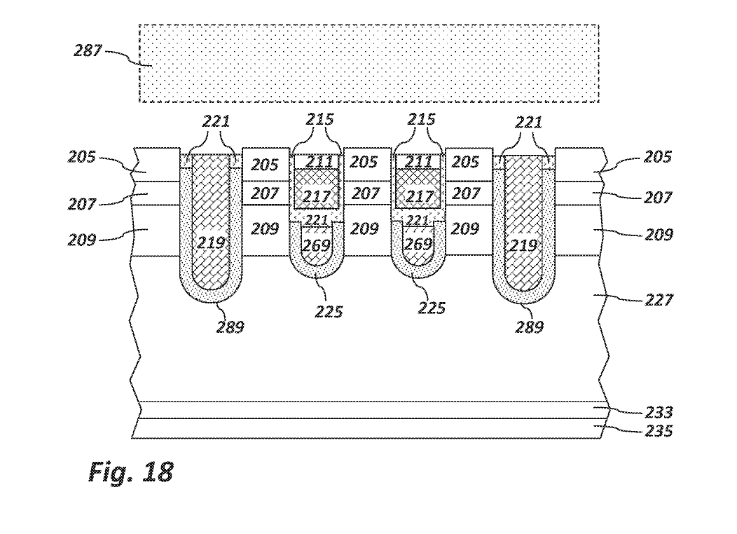

As FIG. 18 illustrates, this layer of dielectric 211 and underlying thermal oxide 221 is subsequently etched back with an RIE/ICP plasma 287. This exposes the silicon carbide ohmic contact regions 205. With selective etching of CVD and spin-on dielectrics 211 and thermal oxide 221 with respect to silicon carbide, such as by use of fluorine plasma, a portion of interlayer dielectric 211 is left over MOS gate layers 217. These portions of layer 211 provide electrical insulation from the top contact overlay, i.e., the source of the MOSFET (or emitter of an IGBT).

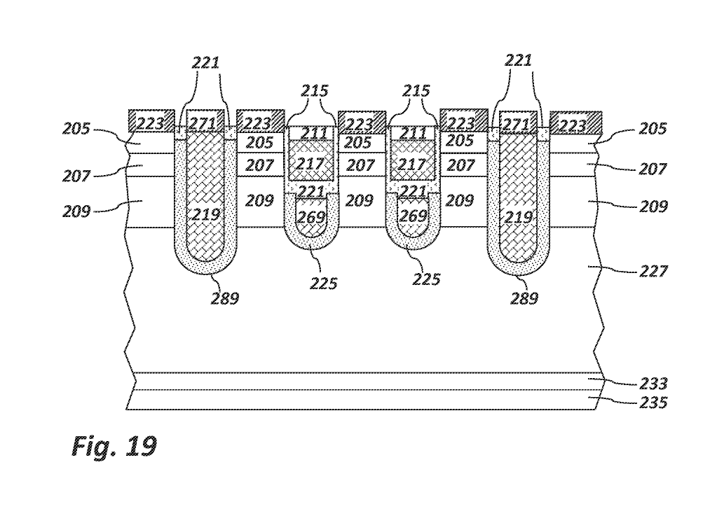

As FIG. 19 illustrates, the ohmic contact regions 223 connecting to silicon carbide n-type contact regions 205 and ohmic contact regions 271 connecting to shielding trench polysilicon fill regions 219 may be are formed in a self-aligned manner.

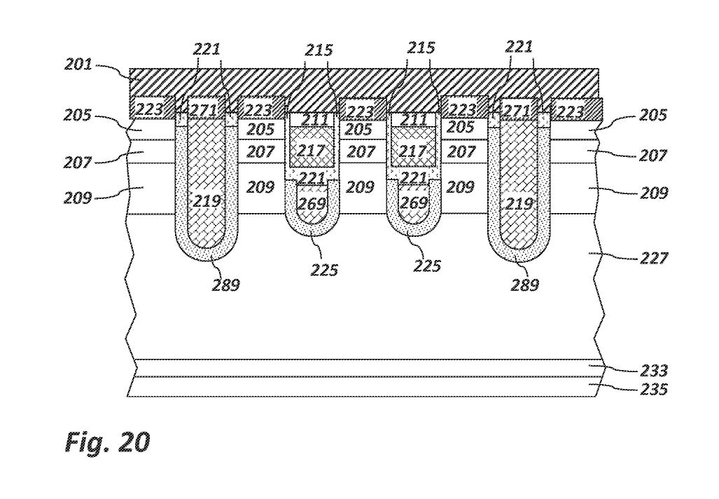

As FIG. 20 illustrates, a top metal overlay 201 is then deposited to connect individual ohmic contact regions 223 and 271 together, and facilitate subsequent wire-bonding.

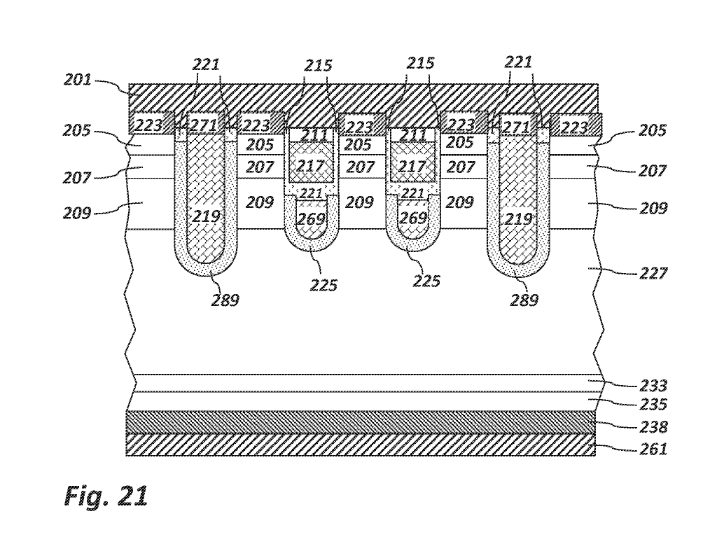

As FIG. 21 illustrates, an ohmic contact is finally formed on the die backside, which is the drain of the MOSFET (or, with the further processing, the collector of an IGBT). This is accomplished by first attaching the front side of the wafer to a wafer carrier with a conventional low-temperature wafer bond, then grinding the substrate, depositing metal, and annealing with a non-equilibrium method such as laser irradiation. Backside overlay 261 is subsequently deposited over ohmic contact 238, and wafer is released from the carrier wafer to the dicing tape for subsequent die singulation. Instead of wafer bonding, substrate grinding and laser-processing, backside ohmic contact 238 may be formed on an original substrate surface concurrently with top-side ohmic contacts 223 and 271.

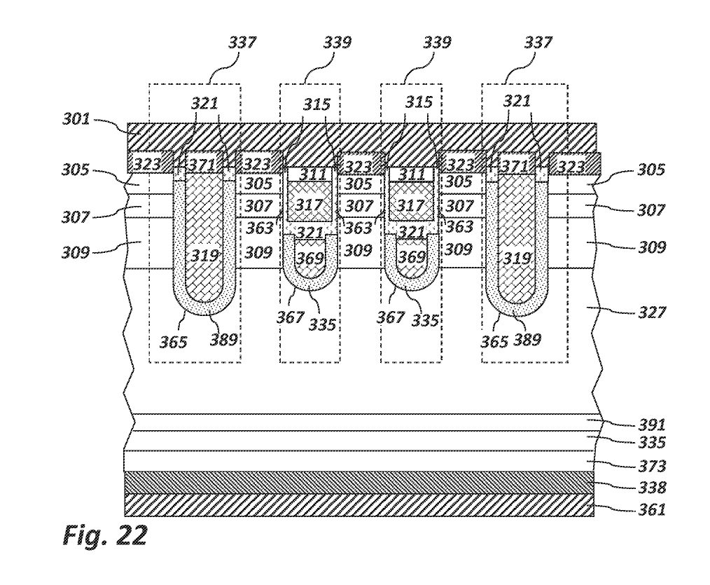

FIG. 22 illustrates an exemplary embodiment of present invention, one of many possible shielded-gate trench n-channel IGBT (n-IGBT) configurations, comprising active trench IGBT regions 339 alternating with gate shielding trench regions 337. An active IGBT trench comprises topside (IGBT emitter) ohmic contact electrode 323 and ohmic contact electrode 371 to shielding trench polysilicon fill, with topside overlay 301 to facilitate wire bonding, topside n-type contact region 305 and p-base 307. P-base 307 is electrically connected to the topside ohmic contact electrode via high dose p+ implants within device unit cell. MOS channels 363 are formed between p-base regions 307, MOS gate oxide 315 on MOS trench side-walls, and polysilicon gate electrodes 317. Gate electrode 317 may be formed of degenerately doped polysilicon. Gate electrode 317 is electrically insulated from the emitter overlay 301 with interlayer dielectric 311, and is connected to an individual gate pad within device die for wafer-level testing and wire-bonding. Region 309 is an n-type doped carrier storage layer, and facilitates current conduction path between low doped n-type drift layer 327 and n-type MOS-channel 363. Bottom of active MOS trenches 367 and shielding trenches 365 are lined up with thick CVD dielectric regions 335 and 389, respectively. Both active IGBT trenches 367 and shielding trenches 365 are filled with degenerately doped polysilicon regions 369 and 319, respectively. Polysilicon regions 369 and 319 are formed during same CVD deposition, but patterned differently. Polysilicon region 319 of shielding trench is connected to the emitter overlay 301 via ohmic contact 371.

MOS trench-based polysilicon source electrode region 369 may be connected to the emitter overlay 301 in certain regions within the device cell the same way the analogous structures 269 and 201 are connected for a MOSFET (as shown above in reference to FIG. 2.) Polysilicon region 369, shorted to the emitter, helps to reduce device Miller capacitance. Polysilicon region 369 is electrically isolated from the active IGBT-gate electrode 317 with a thick silicon dioxide layer 321 formed of oxidized polysilicon. Polysilicon 321 is oxidized together with side-wall MOS gate oxide 315. A thicker dielectric 321 may be formed concurrently with a thinner MOS gate oxide 315 because of difference in oxidation rates of silicon carbide and polysilicon. The IGBT further comprises n-type field stop layer 391, and a p-type doped region 335, which controls minority hole injection into drift layer, and an additional heavily doped p-type layer 373, which facilitates backside collector ohmic contact 338. Collector ohmic contact is coated with collector overlay 361 for die-mounting.

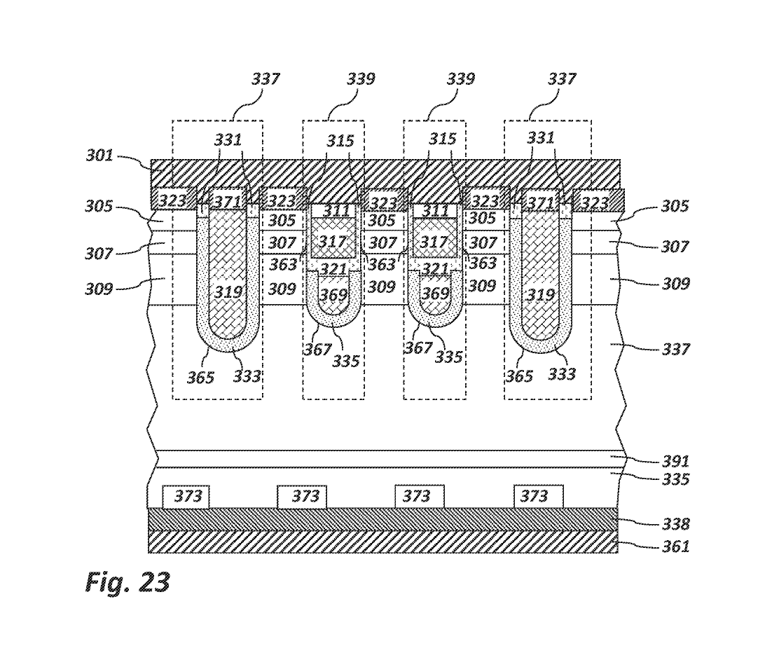

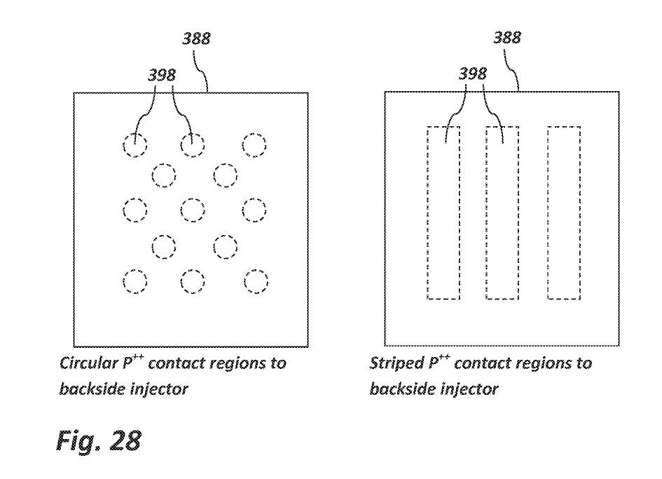

As one skilled in the art would appreciate, such an IGBT process is very similar to the MOSFET process except for the differences in backside processing. The IGBT would be preferred to the MOSFET to create a device above a 10 kV voltage rating, where the thick drift layer, e.g., greater than 100 microns, may be sufficiently mechanically strong to support the wafer during substrate removal by grinding, and die singulation. In such a case, the IGBT device structure, such as shown in FIG. 22, may be formed by completing top the side process with the deposition of emitter overlay 301. The original substrate, which is preferred to be an n-type substrate because of better technological maturity and higher material quality, may then be completely removed by grinding until either epitaxial buffer or drift layer is exposed, as the drift layer thickness can provide required mechanical strength. This can be accomplished by attaching IGBT wafer front side to the carrier wafer with conventional low temperature wafer bond. P-type injector layer of an n-channel IGBT (N-IGBT) injects minority carriers into drift layer, and may be formed with backside p-type ion implants. P-type ion implantation is subsequently performed to form the injector layer, and a heavily doped ohmic contact region 373. Heavily doped ohmic contact region 373 may be discontinuous across the die backside surface, as FIG. 23 illustrates. This may be accomplished with patterned backside ion implants. Field-stop n-type layer 391 may also be ion-implanted together with p-type injector 335 after complete removal of the substrate and original epitaxial buffer layer by grinding. In such a case, the drift layer 227 is exposed, and p-type injector may be implanted together with n-type field stop layer. Both p- and n-type ion implants have to be activated with non-equilibrium dopant activation technique, which would not affect the fully processed wafer front side, such as laser-assisted activation. Backside ohmic contact has also to be formed by non-equilibrium process, such as laser irradiation in stepped pattern. The total ion dose supplied to the wafer during ion implantation of collector contact regions has to be a least factor 10× higher than total ion dose supplied during ion implantation for backside injector, and the total area of high dose collector regions has to be no more than 50% of total backside die area, implanted in either stripe or circular patterns 398, as depicted in FIG. 28.

As one skilled in the art would appreciate, the fabrication process for the invention described herein includes self-aligned definition of all key device features. Although additional photolithographic steps are required, no critical alignment is needed.

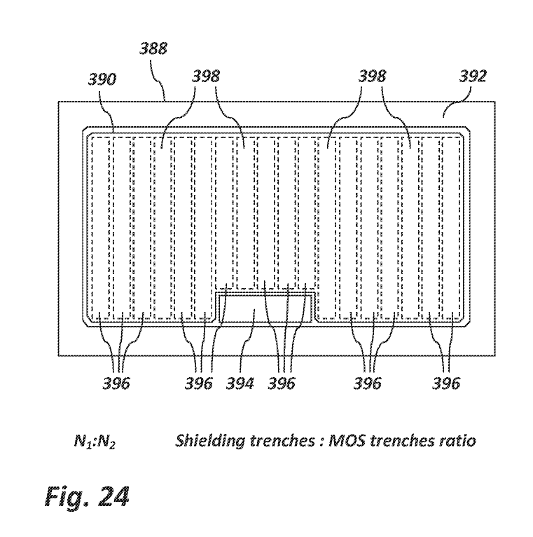

As one skilled in the art would appreciate, the shielding trenches of such MOS-controlled switch (MOSFET or IGBT) are deeper then active MOS or IGBT trenches, as the avalanche breakdown is pinned at the trench bottom, and MOS gate oxide is electrostatically shielded within shallower active MOS trenches from high electric field at avalanche. As one skilled in the art will appreciate, one shielding trench can efficiently shield multiple active MOS-controlled trenches. FIG. 24 illustrates topside view of one of possible layouts of the trench shielded-gate MOS-controlled switch die 388, where shielding trenches 388 are parallel to the active MOS trenches 396 with the ratio N1:N2=3 of shielding trenches 398 to the active MOS-controlled trenches 396. Such a layout comprises large MOSFET source (IGBT emitter) bonding pad 390 and gate bonding pad 394. A wide die periphery 392 between the bonding pads and die edge 388 further comprises edge termination region. Although FIG. 24 shows the ratio N1:N2 equal to three, the ratio maybe one or higher and designed to achieve desired avalanche ruggedness of a discrete switch. Instead of linear arrangement, active MOS and shielding trenches may also be arranged in staggered closed cell, circular or hexagonal configurations.

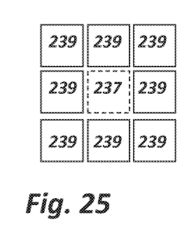

FIG. 25 shows an exemplary embodiment of a staggered closed cell arrangement of active MOS trenches 239 and shielding trenches 237 within the device structure.

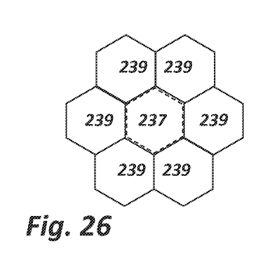

FIG. 26 shows an exemplary embodiment of schematic hexagonal cell arrangement of active MOS trenches 239 and shielding trenches 237 within the device structure.

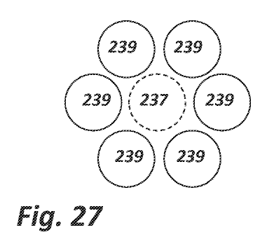

FIG. 27 shows an exemplary embodiment of a cell arrangement of circular active MOS trenches 239 and shielding trenches 237 trenches within the device structure.

As one skilled in the art would appreciate, it is of great practical benefit to align the longest portions of side-walls of MOS trenches, comprising MOS channels, along m-plane (11̅00) or a-plane (112̅0) surfaces in 4H-silicon carbide, as such oriented MOS channels may benefit from the highest possible values of inversion channel carrier mobility among other possible trench orientations. Higher MOS channel mobility would help reducing device on-resistance and hence its conduction losses.

In an example embodiment, the thickness of the n-type contact and p-base layers, for example, may be 0.2 μm and 0.5 μm respectively. The p-base layer and n-type contact layer may be ion-implanted with conventional ion implanters with required energies, such as, for example under 480 keV for the p-base 207 and 100 KeV for the n-type contact. This may provide a method of uniform doping control of the p-base layer through ion implantation instead of epitaxial growth, which in turn results in a uniform and reproducible sheet resistivity, threshold voltage and dv/dt capability.

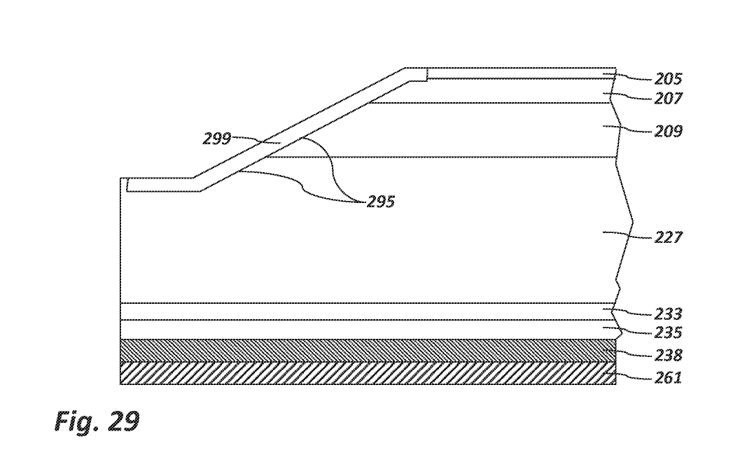

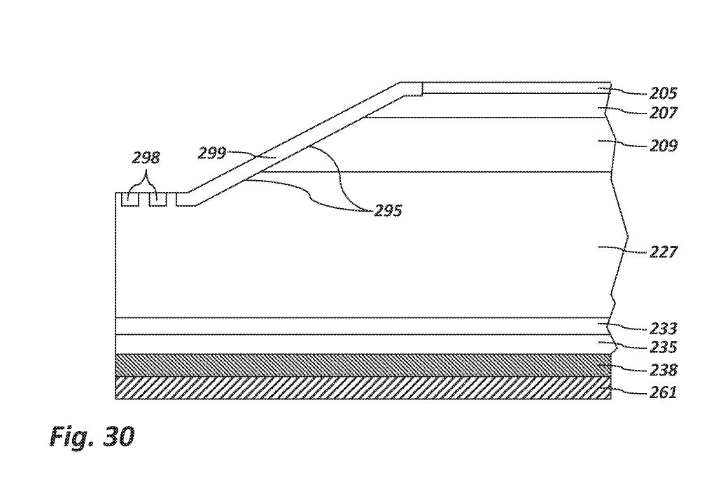

As one skilled in the art will appreciate, the edge termination may be a single or multi-zone junction termination extension (JTE or MJTE), multiple floating guard-rings (MFGR), or a bevel, field-plate or deep mesa isolation formed with an additional manufacturing step. FIG. 29 illustrates the edge termination region of the device die including an etched bevel 295 to facilitate electrical connection to the implanted junction termination extension (JTE) region 299. FIG. 30 illustrates the edge termination region of the device die including a bevel 295 etched through n-type contact layer 205, p-base 207, current spreading layer 209, and reaching into drift layer 227, together with floating guard-rings (FGR) 298 with implanted region 296 of first conductivity type for electrical connection to the p-base 207. Edge termination may also combine FGR and JTE. JTE may also include multiple zones, formed by either implanting different ion doses for individual zones, or by plasma etching of individual zones.

In an example embodiment, the entire structure may be manufactured based on a drift and current spreading layers, without epitaxially grown p-base and n-type contact layers. In the example embodiment, the life-time enhancement may be implemented for very thick drift layers in Silicon Carbide through high-temperature oxidation and subsequent annealing processes. The structure, for example, may also be manufactured on a zero degree off-cut wafer to fully eliminate basal-plane defects in case of Silicon Carbide. For example, the resulting step bunching and surface roughness may be polished off, and N++ n-type contact layer and a p-base may then be co-implanted. For example, this process may be useful for Silicon Carbide IGBTs with over 15 kV ratings, where the minority carrier life-time in as-grown drift layer may not be long enough to provide efficient conductivity modulation in the drift layer. In such process the consumption of the surface layer through life-time enhancement and polishing may be optimized not to consume the n-type current spreading layer (or carrier storage layer of an IGBT).

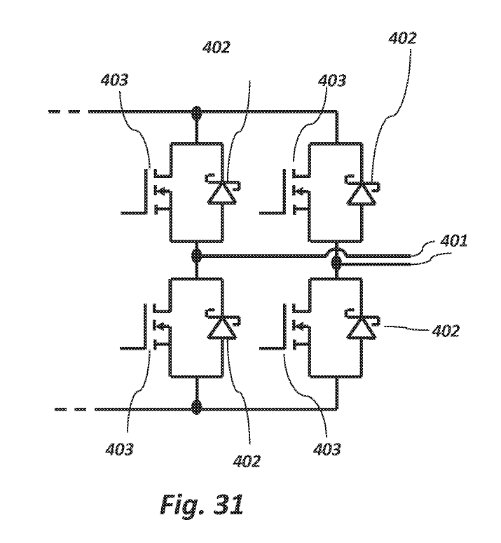

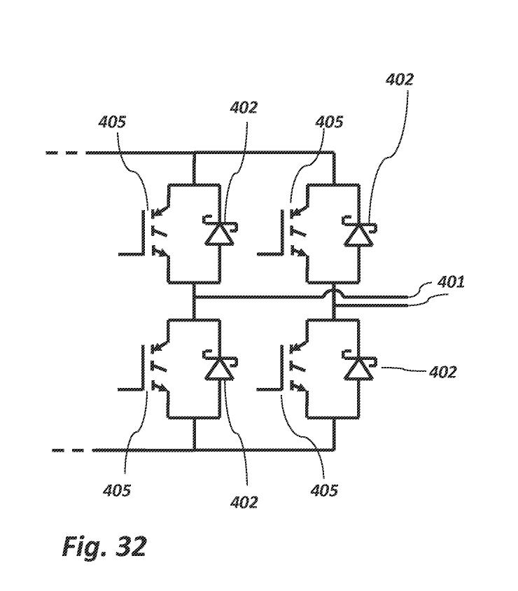

FIG. 31 illustrates an exemplary embodiment of present invention in a full bridge circuit where a shielded-gate n-channel MOSFET is being used with an antiparallel diode. The circuit includes four anti-parallel Schottky/JBS diodes 402 and four n-channel shielded-gate MOSFETs 403 in each of four switch locations, where 401 is the power output of the circuit. Similar configurations are found in most half-bridge, three-phase bridge, and multi-level converter circuits. In hard switched applications, using a Schottky/JBS diode is especially beneficial because that eliminates diode recovery related switching losses, allowing for higher frequency operation, smaller passives, and lower cooling requirements. FIG. 32 illustrates the same circuit, where instead of a shielded-gate n-channel MOSFET, an n-channel IGBTs 405 are being used.

Half-bridge, three phase bridge, and multi-level converter systems built with hybrid WBG semiconductor bipolar switches described herein may be used in a wide variety applications to reduce power losses and reduce system size and weight.

As one skilled in the art would appreciate, trench shielded-gate MOS-controlled switches (MOSFETs and IGBTs) may be designed and manufactured for various operating voltage ratings, such as above 50 V, although devices rated at 650 V or above are of particular interest. Theoretical voltage rating of trench shielded-gate MOS-controlled switch of present invention may be as high as 20 kV using state-of-the-art Silicon Carbide epitaxial growth and device processing technology known in the art. The gate shielding trench width and the thickness of the dielectric fill has to be increased to achieve close to theoretical breakdown voltage of the device. Up to 50 kV rating can also be achieved using thick epitaxial growth of 4H-Silicon carbide material combined with IGBT technology.

As one skilled in the art would appreciate, the built-in body diode of a MOSFET can eliminate the need for an external anti-parallel diode in practical power conversion circuits. The optional external anti-parallel diode may nevertheless be implemented based on specific circuit requirements.

As one skilled in the art will appreciate, the high-voltage MOS-controlled switch, described herein, may be manufactured from conventional silicon carbide polytypes such as 4H-, 6H-, or 3C-SiC.

When ranges are used herein for physical properties, such as molecular weight, or chemical properties, such as chemical formulae, all combinations, and sub combinations of ranges for specific embodiments therein are intended to be included.

The disclosures of each patent, patent application, and publication cited or described in this document are hereby incorporated herein by reference, in its entirety.

Those skilled in the art will appreciate that numerous changes and modifications can be made to the preferred embodiments of the invention and that such changes and modifications can be made without departing from the spirit of the invention. It is, therefore, intended that the appended claims cover all such equivalent variations as fall within the true spirit and scope of the invention.

1. A silicon carbide trench shielded-gate n-channel MOS-controlled switch with trench-based polysilicon source electrode, comprising:
a. a drift layer of the second conductivity (n-type) formed by homo-epitaxial growth with thickness in the range 1 to 1000 microns;
b. a current-spreading (or carrier storage for IGBT) layer of second conductivity type (n-type), formed on top of the drift layer either by epitaxial growth or ion implantation, with thickness in the range 0.5 to 2 microns;
c. a p-base layer of first conductivity type (p-type), formed on top of the channel layer either by epitaxial growth or ion implantation, with thickness in the range 0.02 to 1 microns;
d. a p-base layer is electrical connection to the top ohmic contact electrode (source of a MOSFET or emitter of an IGBT) via high-dose p+ ion implanted regions at specific region(s) within device active area and top ohmic contact electrode;
e. a top contact layer of the second conductivity type (n-type) formed on top of the base layer either by epitaxial growth or ion implantation, with thickness in the range 0.05 to 0.5 microns;
f. plurality of U-shaped MOS trenches formed in the contact layer, base layer, and current-spreading layer, the each U-shaped MOS trench including:
i. a lower portion below the lower boundary of the p-base layer with rounded bottom surface, and an upper portion above the lower boundary of the p-base layer, a first side surface, and a second side surface;
ii. the trenches extending from the top of the contact layer, through the contact layer, through the p-base, through the current spreading layer; and the bottom of the trenches being surrounded by the drift layer;
iii. a top ohmic contact electrode, such as source of MOSFET or emitter of IGBT, formed on top of the contact layer;
iv. a MOS gate electrode in the upper portion of the trench between first and second side surfaces, formed with degenerately doped polysilicon, separated from the adjacent silicon carbide p-base layer on MOS trench side-wall with electrically insulating thermally grown 30-100 nm thick MOS gate oxide;
v. a MOS gate electrode being electrically isolated from the top metal overlay with interlayer dielectric, such as a combination of layers including CVD silicon dioxide, CVD silicon nitride and spin-on-dielectric,
vi. a MOS trench-based polysilicon source electrode, made with degenerately doped polysilicon and intended to reduce device Miller capacitance, formed in the lower portion of each individual MOS trench between first and second side surfaces below the MOS gate;
vii. a MOS trench-based polysilicon source electrode being electrically insulated from silicon carbide trench bottom, first and second side surfaces with thick CVD dielectric;
viii. a MOS trench-based degenerately doped polysilicon source electrode being electrically insulated from the MOS gate electrode with thermally grown oxide on polysilicon surface, formed concurrently with thermal MOS gate oxide;
ix. a thickness of thermal oxide on MOS trench-based degenerately doped polysilicon source electrode being at least a factor of 1.5× thicker than MOS gate oxide on trench first and second side surfaces;
x. a MOS trench-based degenerately doped polysilicon source electrode being electrically connected to the source overlay via raised polysilicon source electrode regions within certain regions in device active area, where MOS gate electrode is not present;
xi. a MOS gate electrode being electrically connected to a gate bonding/probing pad via ohmic contact to raised polysilicon MOS gate layer in certain region within device die;
xii. a first and second side-walls of MOS trenches, comprising MOS channel, all oriented along m-plane (11̅00) or a-plane (112̅0) surfaces in 4H-silicon carbide;
g. plurality of U-shaped shielding trenches formed in the contact layer, base layer, and current-spreading layer, the each U-shaped shielding trench including:
i. a rounded bottom surface, a first side surface, and a second side surface;
ii. the shielding trenches extending from the top of the contact layer, through the contact layer, through the p-base, through the current spreading layer; and the bottom of the trenches being surrounded by the drift layer;
iii. the shielding trenches extending into drift layer by at least 100 nm deeper than MOS trenches;
iv. a top ohmic contact electrode, such as source of MOSFET or emitter of IGBT, formed on top of the contact layer;
v. a shielding trench polysilicon fill, made with degenerately doped polysilicon, formed between first and second side surfaces below the MOS gate;
vi. a shielding trench polysilicon fill being electrically insulated from silicon carbide trench bottom, first and second side surfaces with thick CVD dielectric;
vii. a thick CVD dielectric lining the bottom, first and second surfaces of the shielding trench being deposited concurrently with thick CVD dielectric lining the lower portion of MOS trenches;
viii. a shielding trench polysilicon fill being electrically connected to the source overlay via ohmic contact electrodes formed to the top of polysilicon trench fill;
h. a top metal overlay, connecting individual top ohmic contact electrodes within device die active area;
i. an optional thin thermally grown oxide on the bottom, first and second surfaces of MOS trenches and bottom, first and second surfaces of the shielding trenches, with the thickness of 10-100 nm;
j. a CVD dielectric lining the lower portion of MOS trenches and bottom, first and second surfaces of the shielding trenches is at least factor of 1.5 thicker than the MOS gate oxide;
k. The total portion of device active area occupied by of MOS trenches is at least factor of 2× larger than the area occupied by shielding trenches;
l. MOS trench-based polysilicon source electrode within lower portion of MOS trenches is deposited concurrently with shielding trench polysilicon fill;
m. a contact and metal overlay formed on the wafer side, opposite to the top contact layer, which is either a drain ohmic contact electrode of a MOSFET or collector of an IGBT;
n. an etched bevel at device edge termination region to reach through contact, p-base and current spreading layers and reaching into drift layer to facilitate electrical connection of the p-base layer to the implanted multi-zone junction termination extension (MJTE), multiple floating guard-rings (MFGR), or combination of both.

2. A self-aligned method of forming a silicon carbide trench shielded-gate n-channel MOS-controlled switch with trench-based polysilicon source electrode of claim 1, comprising:
a. forming a drift layer of the second conductivity (n-type) by homo-epitaxial growth;
b. forming a current-spreading (or carrier storage for IGBT) layer of second conductivity type (n-type) by homo-epitaxial growth, on top of the drift layer either by epitaxial growth or ion implantation;
c. forming a p-base layer of first conductivity type (p-type), formed on top of the channel layer either by epitaxial growth or ion implantation;
d. forming P-base layer electrical connection to the top ohmic contact electrode (source of a MOSFET or emitter of an IGBT) via high-dose p+ ion implanted regions at specific region(s) within device active area, and top ohmic contact electrode;
e. forming a top contact layer of the second conductivity type (n-type) formed on top of the base layer either by epitaxial growth or ion implantation;
f. forming plurality of U-shaped MOS trenches of claim 1 in the contact layer, base layer, and current-spreading layer;
g. ing plurality of U-shaped shielding trenches of claim 1 in the contact layer, base layer, and current-spreading layer
h. forming a top metal overlay, connecting individual top ohmic contact electrodes within device die active area;
i. forming optional thin thermally grown oxide on the bottom, first and second surfaces of MOS trenches and bottom, first and second surfaces of the shielding trenches, with the thickness of 10-100 nm;
j. forming CVD dielectric lining in the lower portion of MOS trenches and bottom, first and second surfaces of the shielding trenches;
k. forming MOS trench-based polysilicon source electrode within lower portion of MOS trenches, by depositing it concurrently with shielding trench polysilicon fill;
l. forming a contact and metal overlay on the wafer side, opposite to the top contact layer, thus forming drain ohmic electrode of a MOSFET or collector of an IGBT;
m. forming an etched bevel at device edge termination region to reach through contact, p-base and current spreading layers and reaching into drift layer to facilitate electrical connection of the p-base layer to the implanted multi-zone junction termination extension (MJTE), multiple floating guard-rings (MFGR), or combination of both.

3. A silicon carbide trench shielded-gate n-channel MOS-controlled switch with trench-based polysilicon source electrode of claim 1, wherein the shielding and active MOS trenches comprise linear arrays of unit cells.

4. A silicon carbide trench shielded-gate n-channel MOS-controlled switch with trench-based polysilicon source electrode of claim 1, wherein the square or rectangular shielding and active MOS trenches are interdigitated.

5. A silicon carbide trench shielded-gate n-channel MOS-controlled switch with trench-based polysilicon source electrode of claim 1, wherein the hexagonal shielding and active MOS trenches are arranged.

6. A silicon carbide trench shielded-gate n-channel MOS-controlled switch with trench-based polysilicon source electrode of claim 1, wherein the circular shielding and active MOS trenches are interdigitated.

7. A silicon carbide trench shielded-gate n-channel MOS-controlled switch with trench-based polysilicon source electrode of claim 1, wherein the switch is an n-channel MOSFET, further comprising:
a. a substrate region of second conductivity type;
b. an epitaxially grown buffer layer of second conductivity type formed between the drift layer and the substrate;
c. a drain ohmic contact electrode, with specific contact resistivity of less than 1 mOhm-cm², formed to the exposed substrate side.

8. A silicon carbide trench shielded-gate n-channel MOS-controlled switch with trench-based polysilicon source electrode of claim 1, wherein the switch is an n-channel insulated-gate bipolar transistor (IGBT), further comprising:
a. a substrate region of first conductivity type formed below epitaxial buffer layers;
b. an optional epitaxially grown buffer layer of first conductivity type formed on the substrate;
c. an epitaxially grown buffer layer of second conductivity type, formed between optional epitaxially grown buffer layer of first conductivity type and the drift layer
d. an epitaxially grown buffer layer of second conductivity type acts as a field-stop in IGBT off-state, when the drift layer is fully depleted in order to support the applied drain-to-source voltage;
e. epitaxial buffer layer and the substrate, both of first conductivity type, provide minority carrier injection into the drift layer in on-state, when IGBT conducts high forward current;
f. a collector ohmic contact electrode, with specific contact resistivity of less than 100 mOhm-cm², formed to the exposed substrate side.

9. A silicon carbide trench shielded-gate n-channel MOS-controlled switch with trench-based polysilicon source electrode of claim 1, wherein the switch is an n-channel insulated-gate bipolar transistor (IGBT), further comprising:
a. original n-type substrate, on which device has been fabricated, has been removed by grinding with wafer front side attached to a standard wafer carrier with conventional low-temperature wafer bond;
b. an ion implanted buffer layer of second conductivity type formed below the drift layer, which acts as a field-stop in IGBT off-state, when the drift layer is fully depleted in order to support the applied drain-to-source voltage;
c. an ion implanted minority carrier injector layer of first conductivity type formed below the field-stop layer;
d. a collector contact layer of first conductivity type formed below the field-stop layer by blanket ion implantation, with total ion dose being at least 10× higher than total ion dose implanted for minority carrier injector layer;
e. backside ion implanted dopants being activated via non-equilibrium process, such as laser irradiation, after top-side processing being completed;
f. a collector ohmic contact electrode, with specific contact resistivity of less than 100 mOhm-cm², formed via non-equilibrium process, such as laser irradiation, after backside ion implants had been activated.

10. A silicon carbide trench shielded-gate n-channel IGBT switch with trench-based polysilicon source electrode of claim 9, comprising:
a. a heavily doped collector contact regions of first conductivity type formed within continuous injector layer of first conductivity layer by patterned ion implantation using either a shadow mask or photoresist pattern;
b. the total ion dose supplied to the wafer during ion implantation of collector contact regions has to be at least factor 10× higher than total ion dose supplied during ion implantation for backside injector;
c. the total area of heavily doped collector contact regions being no more than 50% of total backside die area;
d. heavily doped collector contact regions either having stripe or circular patterns.

11. A self-aligned method of forming a trench shielded-gate n-channel MOS-controlled switch with trench-based polysilicon source electrode of claim 7, wherein the switch is an n-channel MOSFET, comprising:
a. forming an epitaxially grown buffer layer of second conductivity type on the original substrate of second conductivity type;
b. forming a drain ohmic contact electrode, with specific contact resistivity of less than 1 mOhm-cm², on the exposed substrate side.

12. A self-aligned method of forming a trench shielded-gate n-channel MOS-controlled switch with trench-based polysilicon source electrode of claim 8, wherein the switch is an n-channel insulated-gate bipolar transistor (IGBT), further comprising:
a. forming an optional epitaxially grown buffer layer of first conductivity type on the original substrate of first conductivity type;
b. forming an epitaxially grown buffer layer of second conductivity type between optional epitaxially grown buffer layer of first conductivity type and the drift layer
c. forming an epitaxially grown buffer layer of second conductivity type acts as a field-stop in IGBT off-state, when the drift layer is fully depleted in order to support the applied drain-to-source voltage;
d. forming epitaxial buffer layer and the substrate, both of first conductivity type, to provide minority carrier injection into the drift layer in on-state, when IGBT conducts high forward current;
e. forming a collector ohmic contact electrode, with specific contact resistivity of less than 100 mOhm-cm², on the exposed substrate side.

13. A self-aligned method of forming a trench shielded-gate n-channel MOS-controlled switch with trench-based polysilicon source electrode of claim 9, wherein the switch is an n-channel insulated-gate bipolar transistor (IGBT), further comprising:
a. removing original n-type substrate, on which device has been fabricated, by grinding with attaching wafer front side to a standard wafer carrier with conventional low-temperature wafer bond;
b. forming ion implanted buffer layer of second conductivity type below the drift layer, which acts as a field-stop in IGBT off-state, when the drift layer is fully depleted in order to support the applied drain-to-source voltage;
c. forming an ion implanted minority carrier injector layer of first conductivity type below the field-stop layer;
d. forming a collector contact layer of first conductivity type formed below the field-stop layer by blanket ion implantation, with total ion dose being at least 10× higher than total ion dose implanted for minority carrier injector layer;
e. activating backside ion implanted dopants via non-equilibrium process, such as laser irradiation, after top-side processing being completed;
f. forming a collector ohmic contact electrode, with specific contact resistivity of less than 100 mOhm-cm², via backside metal deposition and non-equilibrium process, such as laser irradiation, after backside ion implants had been activated.

14. A self-aligned method of forming a trench shielded-gate n-channel IGBT switch with trench-based polysilicon source electrode of claim 13, further comprising:
a. forming a heavily doped collector contact regions of first conductivity type within continuous injector layer of first conductivity layer by patterned ion implantation using either a shadow mask or photoresist pattern;
b. supplying total ion dose to the wafer during ion implantation of collector contact regions at least factor 10× higher than total ion dose supplied during ion implantation for backside injector;
c. forming the total area of heavily doped collector contact regions no more than 50% of total backside die area;
d. forming heavily doped collector contact regions either having stripe or circular patterns.

15. The die layout of a silicon carbide trench shielded-gate n-channel MOS-controlled switch with trench-based polysilicon source electrode of claim 1, wherein silicon carbide semiconductor material includes at least one of 4H-silicon carbide, 6H-silicon carbide, or 3C-silicon carbide.

16. A silicon carbide trench shielded-gate n-channel MOS-controlled switch with trench-based polysilicon source electrode of claim 1, wherein a switch has a breakdown voltage rating at maximum operating junction temperature in the range of from about +1 V to about +50,000 V.

17. A circuit comprising the silicon carbide trench shielded-gate n-channel MOS-controlled switch with trench-based polysilicon source electrode of claim 1.

18. A device comprising the circuit of claim 17.

19. A silicon carbide trench shielded-gate n-channel MOS-controlled switch with trench-based polysilicon source electrode, comprising:
an n-type drift layer formed by homo-epitaxial growth of silicon carbide with thickness in the range 1 to 1000 microns, over monocrystalline 4H-silicon carbide, or other polytype, substrate;
an n-type current-spreading (or carrier storage for IGBT) layer, formed on top of the drift layer by either homo-epitaxial growth or ion implantation, with doping level at least 1.5× different from the drift layer;
plurality of U-shaped active MOS trenches etched in silicon carbide, reaching through the current spreading layer, wherein the bottom of the trenches is being surrounded by the drift layer and including:
a rounded trench bottom, a first side surface, and a second side surface;
a first and second side surfaces of MOS trenches, comprising active MOS channels, deviating from either m-plane (11̅00) or a-plane (112̅0) surfaces in 4H-silicon carbide by no more than 13 degrees of arc;
a 0.1-1.0 micron thick CVD dielectric lining the bottom of the active MOS trench and in contact with MOS trench-based polysilicon source electrode, being deposited concurrently with thick CVD dielectric lining the bottom, first- and second side surfaces of gate shielding trenches;
a MOS trench-based degenerately doped, n- or p-type, polysilicon source (emitter of IGBT) electrode being electrically insulated from the MOS gate electrode with thermally grown oxide on polysilicon surface, and formed concurrently with MOS gate oxide on first and second active MOS trench side surfaces;
a polysilicon trench-based source (emitter of IGBT) electrode being electrically connected to a source (emitter of IGBT) bonding/probing pad via as-deposited or alloyed ohmic contact to raised polysilicon layer in certain region within device die;
a degenerately doped, n- or p-type, polysilicon MOS gate electrode, controlling electrical conductivity of active MOS channels within p-type Pbase layers on first- and second side surfaces of active MOS trenches, being electrically connected to a gate bonding/probing pad via as-deposited or alloyed ohmic contact to raised polysilicon MOS gate layer in certain region within device die;
plurality of U-shaped gate shielding trenches etched in silicon carbide, reaching through the current spreading layer, wherein the bottom of the trenches is being surrounded by the drift layer, and extending into drift layer by at least 100 nm deeper than active MOS trenches, the each U-shaped gate shielding trench including:
a rounded trench bottom, first side surface, and a second side surface;
a first and second side surfaces of shielding trenches, deviating from either m-plane (11̅00) or a-plane (112̅0) surfaces in 4H-silicon carbide by no more than 13 degrees of arc;
a 0.1-1.0 micron thick CVD dielectric lining the bottom, first and second surfaces of the gate shielding trench, being deposited concurrently with thick CVD dielectric lining the lower portion of active MOS trenches;
a shielding trench polysilicon fill being electrically connected to the source overlay via as-deposited or alloyed ohmic contact electrodes formed to the top of polysilicon trench fill;
The total portion of device active area occupied by active MOS trenches is at least factor of 2× larger than the area occupied by gate shielding trenches;
MOS trench-based polysilicon source electrode within lower portion of active MOS trenches is deposited and degenerately doped, p- or n-type, concurrently with gate-shielding trench polysilicon fill;

20. A self-aligned method of forming a silicon carbide trench shielded-gate n-channel MOS-controlled switch with trench-based polysilicon source electrode of claim 1, comprising:
forming an n-type drift layer formed by homo-epitaxial growth of silicon carbide with thickness in the range 1 to 1000 microns, over monocrystalline 4H-silicon carbide, or other polytype, substrate;
forming an n-type current-spreading (or carrier storage for IGBT) layer on top of the drift layer by either homo-epitaxial growth or ion implantation, with doping level at least 1.5× different from the drift layer;
forming plurality of U-shaped active MOS trenches by ICP or RIA etching in silicon carbide, reaching through the current spreading layer, wherein the bottom of the trenches is being surrounded by the drift layer and including:
forming a rounded trench bottom, a first side surface, and a second side surface;
forming first and second side surfaces of MOS trenches, comprising active MOS channels in 4H-silicon carbide, deviating from either along m-plane (11̅00) or a-plane (112̅0) surfaces by no more than 13 degrees of arc;
forming a 0.1-1.0 micron thick CVD dielectric lining the bottom of the active MOS trench and in contact with MOS trench-based polysilicon source electrode, being deposited concurrently with thick CVD dielectric lining the bottom, first- and second side surfaces of gate shielding trenches;
electrically insulating MOS trench-based degenerately doped, n- or p-type, polysilicon source (emitter of IGBT) electrode from the MOS gate electrode with thermally grown oxide on polysilicon surface, formed concurrently with MOS gate oxide on first and second active MOS trench side surfaces;
forming a polysilicon trench-based source (emitter of IGBT) electrode, electrically connected to a source (emitter of IGBT) bonding/probing pad via as-deposited or alloyed ohmic contact to raised polysilicon layer in certain region within device die;
forming a degenerately doped, n- or p-type, polysilicon MOS gate electrode, controlling electrical conductivity of active MOS channels within p-type Pbase layers on first- and second side surfaces of active MOS trenches, being electrically connected to a gate bonding/probing pad via as-deposited or alloyed ohmic contact to raised polysilicon MOS gate layer in certain region within device die;
forming plurality of U-shaped gate shielding trenches by ICP or RIA etching in silicon carbide, reaching through the current spreading layer, wherein the bottom of the trenches is being surrounded by the drift layer, and extending into drift layer by at least 100 nm deeper than active MOS trenches, the each U-shaped gate shielding trench including:
forming a rounded trench bottom, first side surface, and a second side surface;
forming first and second side surfaces of shielding trenches, deviating from either m-plane (11̅00) or a-plane (112̅0) surfaces in 4H-silicon carbide by no more than 13 degrees of arc;
forming a 0.1-1.0 micron thick CVD dielectric lining the bottom, first and second surfaces of the gate shielding trench, deposited concurrently with thick CVD dielectric lining the lower portion of active MOS trenches;
forming a shielding trench polysilicon fill being electrically connected to the source overlay via as-deposited or alloyed ohmic contact electrodes formed to the top of polysilicon trench fill;
defining the total portion of device active area occupied by active MOS trenches being at least factor of 2× larger than the area occupied by gate shielding trenches;
forming MOS trench-based polysilicon source electrode within lower portion of active MOS trenches by depositing and degenerately doping, p- or n-type, concurrently with gate-shielding trench polysilicon fill;

21. A silicon carbide trench shielded-gate n-channel MOS-controlled switch with trench-based polysilicon source electrode of claim 1, wherein an etched bevel at device edge termination region is formed to reach into drift layer to facilitate electrical connection of the p-base layer to the implanted multi-zone junction termination extension (MJTE), multiple floating guard-rings (MFGR), or combination of both;

22. A silicon carbide trench shielded-gate n-channel MOS-controlled switch with trench-based polysilicon source electrode of claim 1, wherein the current spreading layer is selectively not implanted into edge termination region, so that planar silicon carbide surface is present within edge-termination region, where p-base layer is in contact with the implanted multi-zone junction termination extension (MJTE), multiple floating guard-rings (MFGR), or combination of both;

23. A silicon carbide trench shielded-gate n-channel MOS-controlled switch with trench-based polysilicon source electrode of claim 1, wherein an optional thermally grown oxide on the bottom, first and second surfaces of MOS trenches and bottom, first and second surfaces of the shielding trenches, with the thickness of 10-100 nm;

24. A self-aligned method of forming a trench shielded-gate n-channel MOS-controlled switch with trench-based polysilicon source electrode of claim 2, wherein an etched bevel at device edge termination region is formed to reach into drift layer to facilitate electrical connection of the p-base layer to the implanted multi-zone junction termination extension (MJTE), multiple floating guard-rings (MFGR), or combination of both;

25. A self-aligned method of forming a trench shielded-gate n-channel MOS-controlled switch with trench-based polysilicon source electrode of claim 2, wherein the current spreading layer is selectively not implanted into edge termination region, so that planar silicon carbide surface is present within edge-termination region, where p-base layer is in contact with the implanted multi-zone junction termination extension (MJTE), multiple floating guard-rings (MFGR), or combination of both;

26. A self-aligned method of forming a trench shielded-gate n-channel MOS-controlled switch with trench-based polysilicon source electrode of claim 2, wherein a sacrificial oxide layer is grown by dry- or wet oxidation and sacrificial oxide being subsequently removed with hydrofluoric acid containing chemical, preceding the growth of MOS gate oxide.

27. The silicon carbide trench shielded-gate n-channel MOS-controlled switch with trench-based polysilicon source electrode of claim 1, wherein the thick CVD dielectric insulating the MOS trench-based polysilicon source electrode, or the thick CVD dielectric insulating the shielding trench polysilicon fill, comprises silicon nitride.

28. The silicon carbide trench shielded-gate n-channel MOS-controlled switch with trench-based polysilicon source electrode of claim 1, wherein the thick CVD dielectric lining the bottom, first, and second surfaces of the shielding trench comprises silicon nitride.
